(19) United States
(12) Patent Application Publication
(10) Pub. No.: US 2015/0340605 A1
(43) Pub. Date: Nov. 26, 2015

(54) INTEGRATED CIRCUIT DEVICE

(71) Applicant: Kabushiki Kaisha Toshiba, Minato-ku (JP)

(72) Inventors: Hikari TAJIMA, Koganei (JP); Masaki KONDO, Yokkaichi (JP); Tsukasa NAKAI, Yokkaichi (JP); Takashi IZUMIDA, Yokohama (JP); Nobuaki YASUTAKE, Yokkaichi (JP)

(73) Assignee: Kabushiki Kaisha Toshiba, Minato-ku (JP)

(21) Appl. No.: 14/465,028

(22) Filed: Aug. 21, 2014

Related U.S. Application Data
(60) Provisional application No. 62/001,354, filed on May 21, 2014.

(51) Int. Cl. H01L 45/00; H01L 27/24

(52) U.S. Cl. CPC H01L 45/08; H01L 45/1253; H01L 45/1233; H01L 27/2454; H01L 27/2481

(57) ABSTRACT

An integrated circuit device according to an embodiment includes two electrodes and two semiconductor layers. The two electrodes extend in a first direction. The two semiconductor layers are placed between the two electrodes, are spaced from each other in the first direction, and extend in a second direction orthogonal to the first direction. The two electrodes include extending parts extending out so as to come close to each other. In a cross section orthogonal to the second direction, the extending parts extend into a region interposed between a pair of tangent lines. The pair of tangent lines tangent to both the two semiconductor layers and do not cross each other.

### CROSS-REFERENCE TO RELATED APPLICATIONS

This application is based upon and claims the benefit of priority from U.S. Provisional Patent Application 62/001,354, filed on May 21, 2014; the entire contents of which are incorporated herein by reference.

### FIELD

Embodiments described herein relate generally to an integrated circuit device.

### BACKGROUND

Recently, there has been proposed a memory device in which memory cells are integrated in two dimensions or three dimensions. In such a memory device, the memory cell for writing or reading data is selected by selecting one of a plurality of wirings provided parallel to each other. The selection of the wiring can be performed by connecting a TFT (thin film transistor) to the wiring and switching on/off this TFT.

### BRIEF DESCRIPTION OF THE DRAWINGS

FIG. 1 is a perspective view illustrating an integrated circuit device according to a first embodiment;

FIG. 2A is a sectional view illustrating a region RA of FIG. 1, FIG. 2B is a sectional view illustrating a region RB of FIG. 1;

FIG. 3 is a partially enlarged sectional view illustrating an integrated circuit device according to a second embodiment;

FIGS. 4A to 5D are sectional views illustrating a method for fabricating a wiring selecting part in an integrated circuit device according to a third embodiment;

FIGS. 6A to 6C show simulation conditions in a test example; and

FIG. 7 is a perspective view illustrating an integrated circuit device according to a fourth embodiment.

### DETAILED DESCRIPTION

An integrated circuit device according to an embodiment includes two electrodes and two semiconductor layers. The two electrodes extend in a first direction. The two semiconductor layers are placed between the two electrodes, are spaced from each other in the first direction, and extend in a second direction orthogonal to the first direction. The two electrodes include extending parts extending out so as to come close to each other. In a cross section orthogonal to the second direction, the extending parts extend into a region interposed between a pair of tangent lines. The pair of tangent lines tangent to both the two semiconductor layers and do not cross each other.

Embodiments of the invention will now be described with reference to the drawings.

### First Embodiment

First, a first embodiment is described.

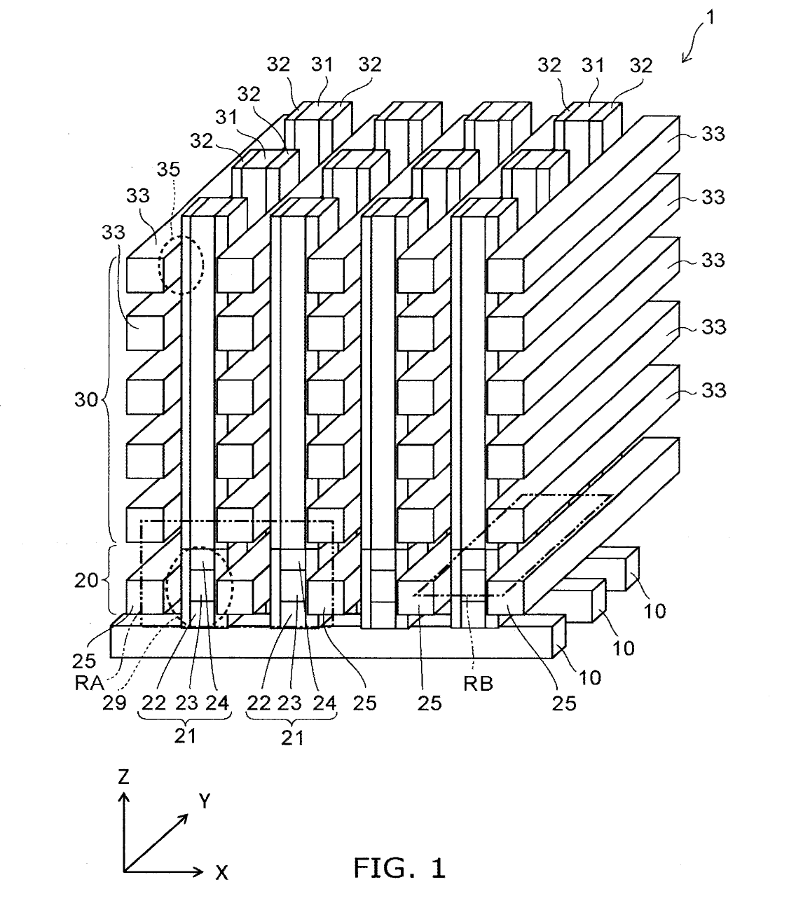

FIG. 1 is a perspective view illustrating an integrated circuit device according to the embodiment.

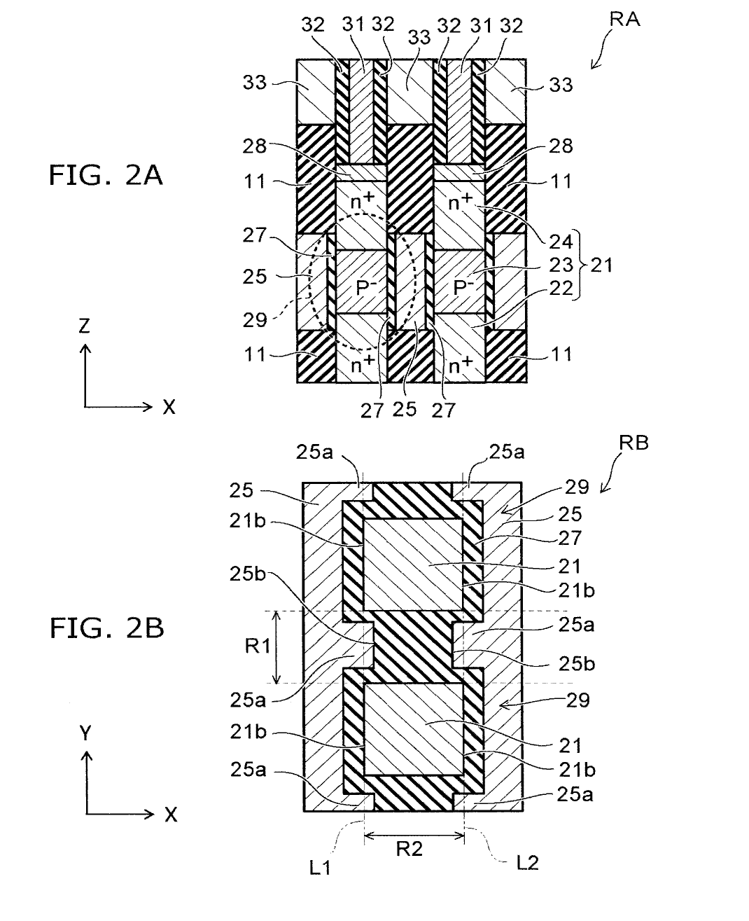

FIG. 2A is a sectional view illustrating the region RA of FIG. 1. FIG. 2B is a sectional view illustrating the region RB of FIG. 1.

For convenience of illustration, FIG. 1 shows only major members.

The integrated circuit device according to the embodiment is a ReRAM (Resistance Random Access Memory).

In the following, for convenience of description, an XYZ orthogonal coordinate system is adopted in this specification.

As shown in FIG. 1, the integrated circuit device 1 according to the embodiment includes a plurality of global bit lines 10 extending in the X-direction. The plurality of global bit lines 10 are arranged periodically along the Y-direction. The global bit line 10 is formed from e.g. an upper portion of a silicon substrate defined by a device isolation insulator (not shown). Alternatively, the global bit line 10 is formed from e.g. polysilicon on an insulating film (not shown) provided on a silicon substrate (not shown).

A wiring selecting part 20 is provided on the global bit line 10. A memory part 30 is provided on the wiring selecting part 20.

As shown in FIGS. 1, 2A, and 2B, the wiring selecting part 20 includes a plurality of silicon pillars 21. The plurality of silicon pillars 21 are arranged like a matrix along the X-direction and the Y-direction. Each silicon pillar 21 extends in the Z-direction. A plurality of silicon pillars 21 arranged along the X-direction are commonly connected to one global bit line 10. Each silicon pillar 21 includes an n⁺-type portion 22, a p⁻-type portion 23, and an n⁺-type portion 24 arranged in this order along the Z-direction from the lower side, i.e., the global bit line 10 side. Here, the relationship between the n-type and the p-type may be reversed. The p⁻-type portion 23 can be replaced by an n⁻-type portion.

The n⁺-type portions 22 and 24 are formed from e.g. silicon doped with impurity serving as a donor. The p⁻-type portion 23 is formed from e.g. silicon doped with impurity serving as an acceptor. The effective impurity concentration of the p⁻-type portion 23 is lower than the effective impurity concentration of the n⁺-type portions 22 and 24. The effective impurity concentration refers to the concentration of impurity contributing to the conduction of the semiconductor material. For instance, in the case where the semiconductor material contains both the impurity serving as a donor and the impurity serving as an acceptor, the effective impurity concentration refers to the concentration except the donor and the acceptor canceling each other.

A gate electrode 25 extending in the Y-direction is provided between the silicon pillars 21 in the X-direction. The gate electrodes 25 are located at nearly the same position in the Z-direction. The gate electrode 25 is formed from e.g. polysilicon. As viewed in the X-direction, the gate electrode 25 overlaps an upper part of the n⁺-type portion 22, the entirety of the p⁻-type portion 23, and a lower part of the n⁺-type portion 24.

A gate insulating film 27 made of e.g. silicon oxide is placed between the silicon pillar 21 and the gate electrode 25. A barrier metal layer 28 can be provided on the upper surface of the silicon pillar 21. The barrier metal layer 28 is e.g. a stacked film in which a lower layer made of titanium silicide (TiSi) and an upper layer made of titanium nitride (TiN) are stacked.

The silicon pillar 21 including the n⁺-type portion 22, the p⁻-type portion 23, and the n⁺-type portion 24, the gate insulating film 27, and the gate electrode 25 constitute e.g. an n-channel type TFT 29.

The memory part 30 includes a plurality of local bit lines 31. The plurality of local bit lines 31 are arranged like a matrix along the X-direction and the Y-direction. Each local bit line 31 extends in the Z-direction. The lower end of each local bit line 31 is connected to the upper end of the corresponding silicon pillar 21. The local bit line 31 is formed from e.g. polysilicon.

A resistance change film 32 as a memory element is provided on two side surfaces directed to both sides in the X-direction of each local bit line 31. The resistance change film is made of e.g. a metal oxide. For instance, upon application of a voltage of a certain level or more, filaments are formed inside, and the resistance change film 32 turns to a low resistance state. Upon application of a voltage with polarity opposite thereto, the filaments are broken, and the resistance change film 32 turns to a high resistance state.

A plurality of local word lines 33 are provided between the local bit lines 31 adjacent in the X-direction and between the resistance change films 32. The plurality of local word lines 33 are arranged like a matrix along the X-direction and the Z-direction. Each local word line 33 extends in the Y-direction. Each local word line 33 is in contact with two resistance change films 32 on both sides in the X-direction. In particular, a plurality of local word lines 33 arranged in a line along the Z-direction are in contact with a common resistance change film 32.

One local bit line 31, one local word line 33, and a portion of the resistance change film 32 sandwiched therebetween constitute a memory cell 35. Thus, a plurality of memory cells 35 are series connected to one TFT 29. In the memory part 30 as a whole, a plurality of memory cells 35 are arranged like a three-dimensional matrix along the X-direction, the Y-direction, and the Z-direction.

In the integrated circuit device 1, an interlayer insulating film 11 is provided so as to embed the global bit lines 10, the silicon pillars 21, the gate electrodes 25, the gate insulating films 27, the local bit lines 31, the resistance change films 32, and the local word lines 33.

Furthermore, as shown in FIG. 2B, an extending part 25a extending out in the X-direction is provided on both side surfaces of the gate electrode 25 directed to the X-direction. In the X-Y cross section passing through the gate electrode 25, the extending part 25a is provided in a region R1 between two silicon pillars 21 adjacent in the Y-direction. Suppose a pair of tangent lines L1 and L2 being tangent to both the two silicon pillars 21 adjacent in the Y-direction and not crossing each other. Then, the extending part 25a extends into a region R2 interposed between the tangent line L1 and the tangent line L2. That is, the tip 25b of the extending part 25a is located in the overlapping portion of the region R1 and the region R2. However, the extending parts 25a of different gate electrodes 25 are not in contact with each other.

In the embodiment, the silicon pillar 21 is shaped like a generally quadrangular prism. Thus, in the X-Y cross section, the silicon pillar 21 is shaped like a rectangle. The pair of tangent lines L1 and L2 both extend in the Y-direction and include a pair of sides 21b extending in the Y-direction at the outer edge of one silicon pillar 21.

Here, the aforementioned positional relationship between the silicon pillar 21 and the extending part 25a in the X-Y cross section can be determined by e.g. cross-sectional SEM (Scanning Electron Microscope) observation.

Next, the effect of the embodiment is described.

As shown in FIG. 2B, in the integrated circuit device 1 according to the embodiment, the gate electrode 25 includes an extending part 25a. Thus, the portion of the outer periphery of the silicon pillar 21 opposed to the gate electrode 25 is larger than that in the case where the extending part 25a is not provided. This increases the portion of the silicon pillar 21 capable of forming a channel by the gate electrode 25, and increases the effective gate width. As a result, the on-current flowing at the time of turning on the TFT 29 is increased, and the leakage current (off-current) flowing at the time of turning off the TFT 29 is decreased. Thus, the ratio of on-current to off-current in the silicon pillar 21 can be increased, and the operation margin is expanded. As a result, the operation of the integrated circuit device 1 is stabilized.

Furthermore, in the integrated circuit device 1, the extending parts 25a opposed to each other are not in contact with each other. Thus, the gate electrode 25 does not completely surround the outer periphery of the silicon pillar 21. As a result, electric field concentration on the corner of the silicon pillar 21 can be relaxed compared with the case where the outer periphery of the silicon pillar 21 is completely surrounded with the gate electrode 25. This suppresses impact ionization in the silicon pillar 21 and stabilizes the operation of the integrated circuit device 1.

The embodiment has been described with reference to the example in which the extending parts 25a are formed on both side surfaces of the gate electrode 25 directed to the X-direction. However, the invention is not limited thereto. For instance, the extending part 25a may be formed on only one side surface of the gate electrode 25 directed to the X-direction. Alternatively, the extending parts 25a may be formed on both side surfaces of every other electrode 25.

The embodiment has been described with reference to the example in which the resistance change film 32 is provided as a memory element. However, the memory element is not limited thereto. For instance, the memory element may be a PRAM (phase random access memory) element or an MTJ (magnetic tunnel junction) element.

### Second Embodiment

Next, a second embodiment is described.

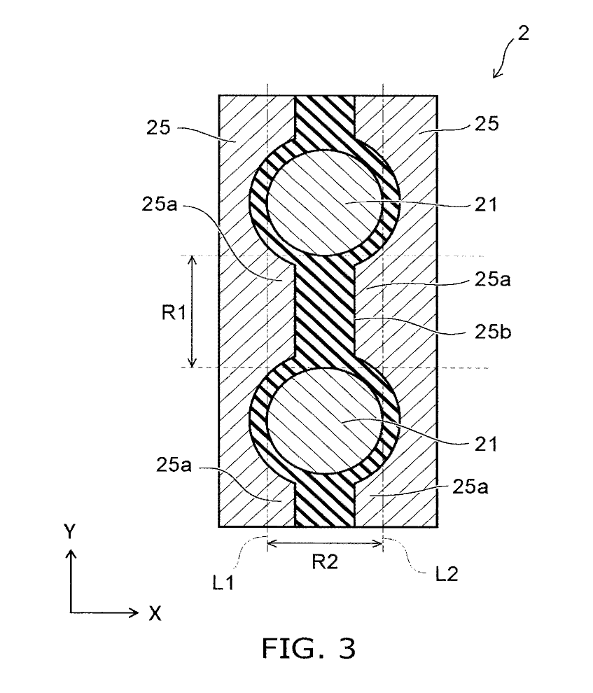

FIG. 3 is a partially enlarged sectional view illustrating an integrated circuit device according to the embodiment.

FIG. 3 corresponds to the region RB of FIG. 1.

As shown in FIG. 3, in the integrated circuit device 2 according to the embodiment, the silicon pillar 21 is shaped like a generally circular cylinder narrowed downward. Thus, the silicon pillar 21 is shaped like a circle in the X-Y cross section. The side surface of the gate electrode 25 opposed to the silicon pillar 21 is curved along the outer surface of the silicon pillar 21.

Also in the embodiment, as in the above first embodiment, the tip 25b of the extending part 25a of the gate electrode 25 is located inside the overlapping portion of the region R1 and the region R2.

According to the embodiment, no corner is formed in the silicon pillar 21. Thus, there is no electric field concentration on the corner. This can suppress impact ionization more reliably. Furthermore, the side surface of the gate electrode 25 is curved along the outer surface of the silicon pillar 21. Thus, the distance between the gate electrode 25 and the silicon pillar 21 is uniform. This can relax electric field concentration. The configuration and effect of the embodiment other than the foregoing are similar to those of the above first embodiment.

### Third Embodiment

Next, a third embodiment is described.

The embodiment is a method for manufacturing the integrated circuit device according to the above first and second embodiments. The embodiment is described primarily about a method for fabricating the wiring selecting part. The shape of the silicon pillar 21 and the gate electrode 25 illustrated in the embodiment is slightly different from those of the above first and second embodiments. However, the manufacturing method is essentially similar.

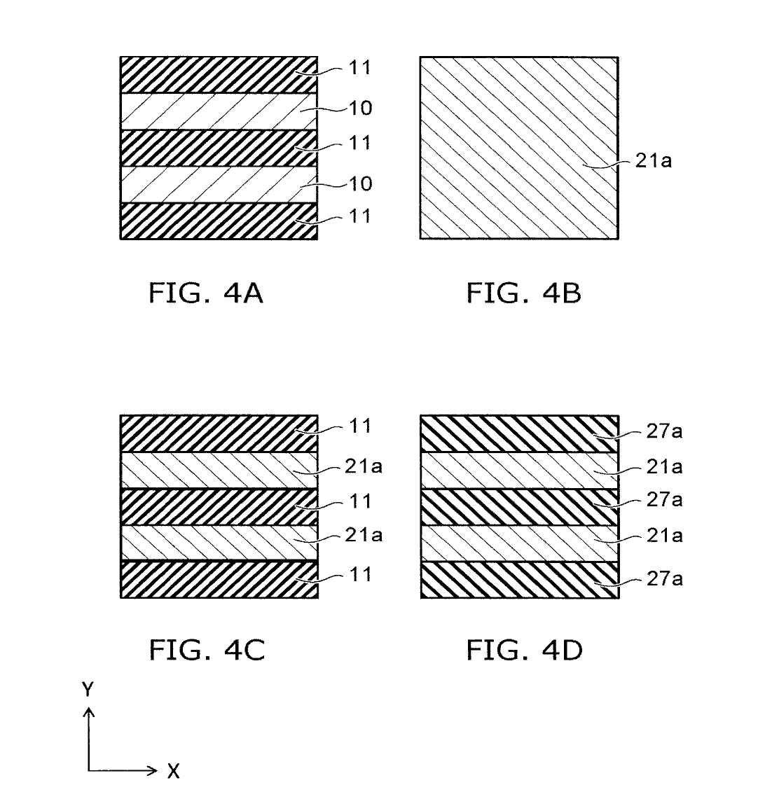

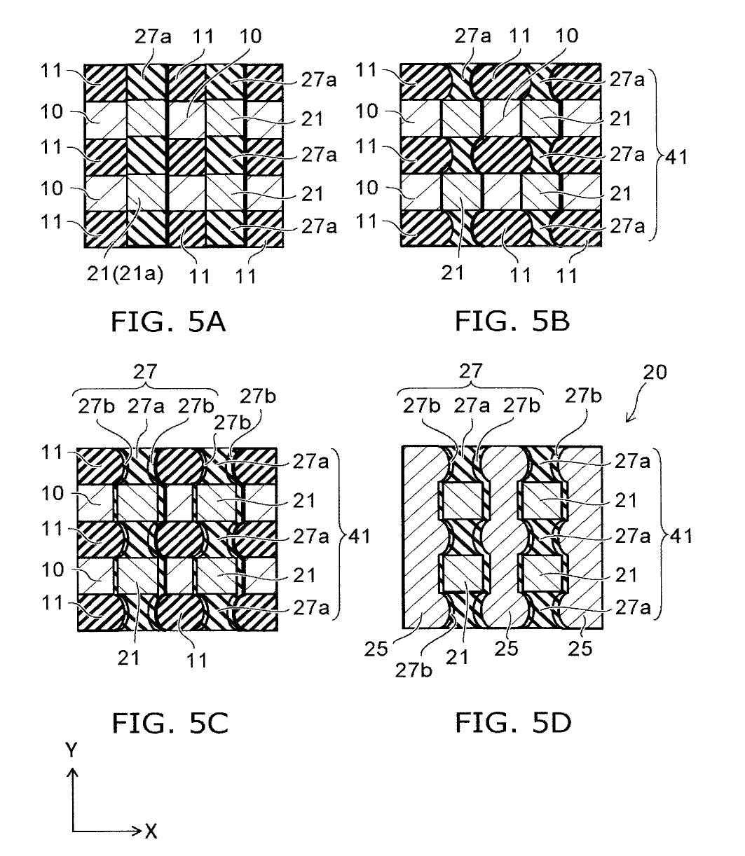

FIGS. 4A to 5D are sectional views illustrating the method for fabricating the wiring selecting part in the integrated circuit device according to the embodiment.

First, as shown in FIG. 4A, a plurality of global bit lines 10 extending in the X-direction are formed. An interlayer insulating film 11 is embedded between the global bit lines 10.

Next, as shown in FIG. 4B, an n⁺-type silicon layer, a p⁻-type silicon layer, and an n⁺-type silicon layer are stacked in this order on the entire surface to form a silicon film 21a.

Next, as shown in FIG. 4C, the silicon film 21a is processed into a line-and-space pattern extending in the X-direction. At this time, the silicon film 21a is left on the global bit lines 10.

Next, as shown in FIG. 4D, a gate insulating film 27a made of e.g. silicon oxide is embedded between the silicon films 21a.

Next, as shown in FIG. 5A, the structural body in which the silicon films 21a and the gate insulating films 27a are alternately arranged along the Y-direction is processed into a line-and-space pattern extending in the Y-direction. Thus, the silicon film 21a is divided along both the X-direction and the Y-direction to constitute silicon pillars 21.

Next, as shown in FIG. 5B, isotropic etching is performed under the conduction such that silicon oxide is selectively etched relative to silicon. For instance, wet etching is performed with hydrofluoric acid and ammonia. Thus, the side surface of the gate insulating film 27a directed to the X-direction is selectively side-etched and set back concavely.

Next, as shown in FIG. 5C, for instance, silicon oxide is deposited and etched back. Thus, a gate insulating film 27b is formed on both side surfaces of the structural body 41 in which the silicon pillars 21 and the gate insulating films 27a are arranged alternately along the Y-direction. The gate insulating films 27a and 27b constitute a gate insulating film 27.

Next, as shown in FIG. 5D, a conductive material such as silicon doped with impurity is deposited, and CMP (chemical mechanical polishing) is performed on the upper surface thereof. Thus, a gate electrode 25 is embedded between the structural bodies composed of the structural body 41 and the gate insulating film 27b. Accordingly, a wiring selecting part 20 is fabricated.

Next, as shown in FIG. 1, a memory part 30 is formed on the wiring selecting part 20. Thus, the integrated circuit device 1 is manufactured.

Next, the effect of the embodiment is described.

In the embodiment, in the step shown in FIG. 5B, the gate insulating film 27a is side-etched to set back the side surface of the gate insulating film 27a. In the step shown in FIG. 5D, a gate electrode 25 is embedded between the structural bodies composed of the silicon pillars 21 and the gate insulating film 27a. Thus, the extending part 25a can be easily formed. Accordingly, the increase of manufacturing cost due to the formation of the extending part 25a is small.

In the step shown in FIG. 5B, a mask material having a generally rectangular shape narrower than the silicon pillar 21 may be formed on the gate insulating film 27a by lithography technique. Subsequently, the mask material may be used as a mask to perform isotropic etching. Thus, the gate insulating film 27a may be etched. Accordingly, the gate insulating film 27 as shown in FIG. 2B can be formed. Thus, the integrated circuit device according to the above first embodiment can be manufactured.

### Test Example

Next, a test example illustrating the effect of the above first embodiment is described.

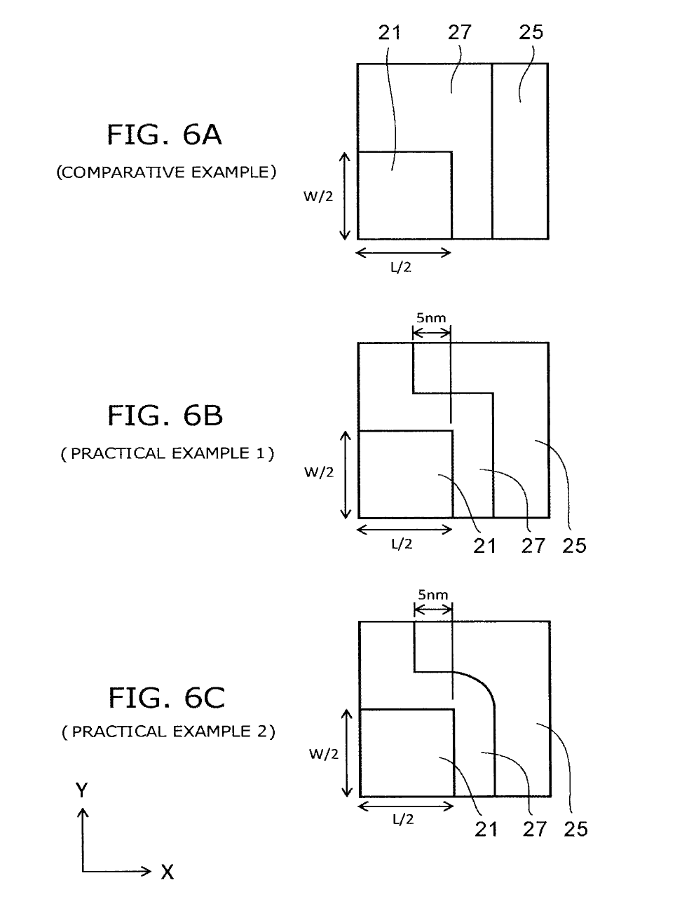

FIGS. 6A to 6C show simulation conditions in the test example. FIG. 6A shows the comparative example. FIG. 6B shows the practical example 1. FIG. 6C shows the practical example 2.

The common condition is shown in TABLE 1.

TABLE 1

| | |
|---|---|
| Material of silicon pillar 21 | Silicon (Si) |
| Material of gate insulating film 27 | Silicon oxide (SiO₂) |
| Material of gate electrode 25 | Polysilicon |
| Cross-sectional shape of silicon pillar 21 | Rectangle |
| X-direction length (L) of silicon pillar 21 | 48 nm |
| Y-direction length (W) of silicon pillar 21 | 24, 48 nm (2 levels) |
| Y-direction length of gate electrode 25 | 210 nm |
| Thickness of gate insulating film 27 | 5 nm |
| Impurity concentration of p-type portion 23 | 4 × 10¹⁷ cm⁻³ |

As shown in FIGS. 6A to 6C and TABLE 1, in the test example, the silicon pillar 21 was assumed to be a silicon pillar with a cross section shaped like a square or rectangle. The gate insulating film 27 was assumed to be a film made of silicon oxide. The gate electrode 25 was assumed to be an electrode made of polysilicon. The distance between the silicon pillar 21 and the gate electrode 25 was set to 5 nm.

The comparative example was assumed to have a shape in which the gate electrode 25 includes no extending part. The practical example 1 was assumed to have a shape in which the gate electrode 25 includes an extending part 25a. The practical example 2 was assumed to have a shape in which the root of the extending part 25a is rounded in contrast to the shape of the practical example 1. The extending part 25a was extended 5 nm beyond the extension line of the side of the silicon pillar 21 extending in the Y-direction. That is, the overlapping amount of the silicon pillar 21 and the extending part 25a was set to 5 nm as viewed in the Y-direction.

Simulation was performed under this condition to calculate the on-current and the off-current flowing in each silicon pillar 21. The result is shown in TABLE 2.

TABLE 2

| | | | | Practical |
|---|---|---|---|---|
| | | Comparative | Practical | example 2 |
| | | example | example 1 | With |
| | | Without | With | extending |
| | Gate width W | extending | extending | part, corners |
| | (nm) | part | part | rounded |
| On-current | 48 | 28.3 | 33.0 | 33.1 |
| (μA) | 24 | 12.5 | — | 16.7 |
| Off-current | 48 | 1.4 | 1.1 | 1.1 |
| (nA) | 24 | 0.32 | — | 0.15 |

As shown in TABLE 2, by comparison between the practical example 1 and the practical example 2, no substantial difference was found in both the on-current and the off-current. On the other hand, by comparison between the practical example 2 and the comparative example, in the case of a silicon pillar with cross-sectional dimensions W=24 nm and L=48 nm, the on-current increased by approximately 34%, and the off-current decreased by approximately 54%. In the case of a silicon pillar with cross-sectional dimensions W=48 nm and L=48 nm, the on-current increased by approximately 17%, and the off-current decreased by approximately 22%. Thus, the effect of increasing the on-current and decreasing the off-current was achieved by providing an extending part in the gate electrode.

### Fourth Embodiment

Next, a fourth embodiment is described.

The embodiment is an example of applying the wiring selecting part 20 in the above first and second embodiments to an MRAM (magnetoresistive random access memory).

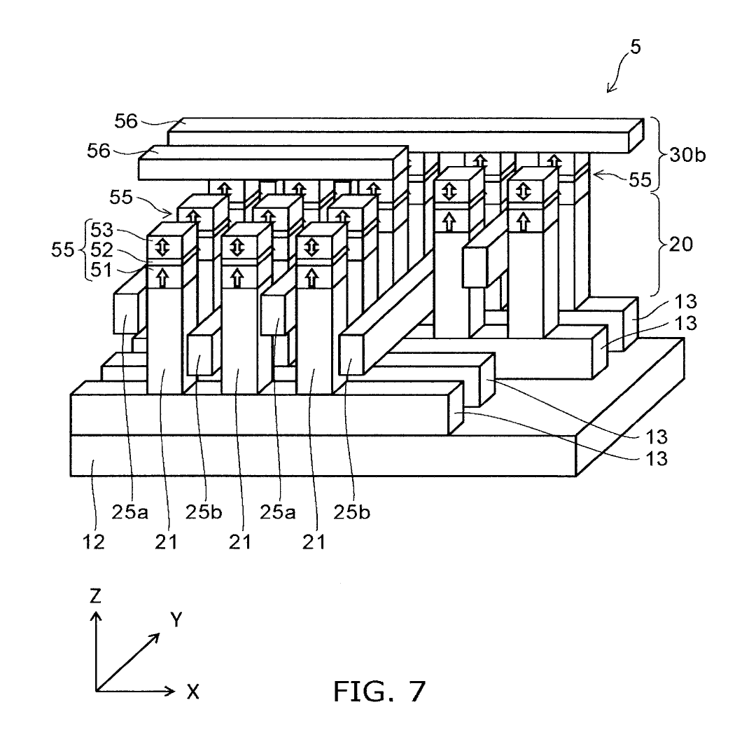

FIG. 7 is a perspective view illustrating an integrated circuit device according to the embodiment.

As shown in FIG. 7, in the integrated circuit device 5 according to the embodiment, an upper portion of a monocrystalline silicon substrate 12 is processed into a plurality of local source lines 13. The plurality of local source lines 13 are arranged periodically along the Y-direction. Each local source line 13 extends in the X-direction. The local source lines 13 are electrically isolated from each other by STI (shallow trench isolation), buried insulating film, or impurity concentration profile like the conventional device isolation. The plurality of local source lines 13 may be collected into a single line.

A wiring selecting part 20 as in the above first embodiment is provided on the wiring layer including the plurality of local source lines 13. In the embodiment, the channel of the wiring selecting part 20 is formed by directly processing the silicon substrate 12. Thus, the channel is formed from monocrystalline silicon. This can increase the on-current compared with the case of forming the channel from polysilicon.

In the integrated circuit device 5, a memory part 30b is provided on the wiring selecting part 20. In the memory part 30b, an MTJ (magnetic tunnel junction) element 55 is provided as a memory element on each semiconductor member 21. The MTJ element 55 is a kind of magnetoresistive elements. In the MTJ element 55, a pinned layer 51 connected to the semiconductor member 21 and made of a perpendicular magnetization film with a pinned magnetization direction, an insulating layer 52, and a memory layer 53 made of a perpendicular magnetization film with a movable magnetization direction are stacked in this order from the lower side. A local bit line 56 extending in the X-direction is provided on the MTJ element 55. Each local bit line 56 is placed directly above the corresponding local source line 13. The local bit lines 56 are commonly connected to the memory layers 53 of a plurality of MTJ elements 55 arranged in a line along the X-direction.

The configuration, manufacturing method, operation, and effect of the embodiment other than the foregoing are similar to those of the above first to third embodiments.

The embodiments described above can realize an integrated circuit device having high operational stability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. An integrated circuit device comprising:
two electrodes extending in a first direction; and
two semiconductor layers placed between the two electrodes, spaced from each other in the first direction, and extending in a second direction orthogonal to the first direction,
at least one of the two electrodes including an extending part extending out so as to come close to the other electrode between the two semiconductor layers, and
in a cross section orthogonal to the second direction, the extending part extending into a region interposed between a pair of tangent lines being tangent to both the two semiconductor layers and not crossing each other.

2. The device according to claim 1, wherein each of the two electrodes includes the extending part.

3. The device according to claim 1, wherein the semiconductor layer is shaped like a rectangle in the cross section.

4. The device according to claim 3, wherein the tangent line includes a side extending in the first direction at an outer edge of one of the semiconductor layers in the cross section.

5. The device according to claim 1, wherein the semiconductor layer is shaped like a circle in the cross section.

6. The device according to claim 5, wherein a side surface of the electrode is curved along an outer surface of the semiconductor layer.

7. The device according to claim 1, further comprising:
an insulating film embedded between the two electrodes and the two semiconductor layers.

8. The device according to claim 1, wherein
each of the semiconductor layers includes:
a first portion of a first conductivity type;
a second portion of a second conductivity type; and
a third portion of the first conductivity type,
the first portion, the second portion, and the third portion are arranged in this order along the second direction, and
the electrode overlaps the second portion as viewed in a third direction orthogonal to both the first direction and the second direction.

9. The device according to claim 1, further comprising:
two memory elements connected to an end part of the semiconductor layer on one side of the second direction; and
a first wiring extending in the first direction and connected to the two memory elements.

10. The device according to claim 9, further comprising:
two second wirings respectively connected to the end parts of the two semiconductor layers on the one side and extending in the second direction; and
two third wirings respectively connected to end parts of the two semiconductor layers on the other side of the second direction,
wherein the memory element is connected between the first wiring and the second wiring.

11. The device according to claim 9, wherein the memory element is a resistance change film.
